(19) United States
(12) Patent Application Publication
(10) Pub. No.: US 2015/0077937 A1
(43) Pub. Date: Mar. 19, 2015

(54) APPARATUS FOR COOLING BOARD MOUNTED OPTICAL MODULES

(71) Applicant: Alcatel Lucent, Paris (FR)

(72) Inventors: John Daly, Paris (FR); Brian Donnelly, Paris (FR); Nicholas Jeffers, Paris (FR); Wei Ling, Paris (FR); Salvatore J. Messana, Paris (FR); Paul M. Rominski, Paris (FR)

(73) Assignee: Alcatel Lucent, Paris (FR)

(21) Appl. No.: 14/026,992

(22) Filed: Sep. 13, 2013

(51) Int. Cl. H05K 7/20; H04B 10/40

(52) U.S. Cl. CPC H05K 7/20218; H04B 10/40; H05K 7/20336; H05K 7/20509
USPC 361/700; 361/699; 165/104.33

(57) ABSTRACT

An apparatus comprising a fluid-circulator loop configured to be located on a circuit board, wherein a heat-removal portion of the fluid-circulator loop is configured to be located adjacent to an optical transceiver module on the circuit board.

### TECHNICAL FIELD

The present invention is directed, in general, to a board mounted cooling apparatus and methods for manufacturing the same.

### BACKGROUND

This section introduces aspects that may be helpful to facilitating a better understanding of the inventions. Accordingly, the statements of this section are to be read in this light and are not to be understood as admissions about what is in the prior art or what is not in the prior art.

Optical networking devices often implement an input/output board having multiple independently hot-swappable optical transceivers modules compactly mounted thereon. The transceivers generate substantially amounts of heat which must be removed to ensure the proper operation of the transceivers. Heat generated by increasingly densely packed board mounted optical transceivers (e.g., form-factor transceivers) with ever-increasing power requirements presents a challenge for present thermal management strategies.

### SUMMARY

One embodiment includes an apparatus, comprising a fluid-circulator loop configured to be located on a circuit board, wherein a heat-removal portion of the fluid-circulator loop is configured to be located adjacent to an optical transceiver module on the circuit board.

Any embodiments of the apparatus can further include the circuit board and/or a plurality of the optical transceiver modules arranged to situate at least one set of in-line optical transceivers on the circuit board.

In any embodiments of the apparatus, optical transceivers can be located inside of one or more transceiver cages of one of more of the optical transceiver modules and the heat-removal portion of the fluid-circulator loop can contact at least one of the transceiver cages or the optical transceivers.

In any embodiments of the apparatus, one or more optical transceivers can be located inside of one or more transceiver cages of a plurality of the optical transceiver modules, and the optical transceivers can be small form factor hot-swappable pluggable transceivers.

In any embodiments of the apparatus, an optical transceiver can be located inside of a transceiver cage of the optical transceiver module, and the transceiver cage can further include a spring-loaded structure configured to push the optical transceiver towards an interior surface of the transceiver cage, the interior surface being proximate to the heat-removal portion of the fluid-circulator loop that contacts the transceiver cage or the optical transceiver.

In any embodiments of the apparatus, the heat-removal portion of the fluid-circulator loop can contact a surface of transceiver cage or the optical transceiver of the optical transceiver modules, and, the transceiver cage and the heat-removal portion can be held together and to the board by a tensioning device.

In any embodiments of the apparatus, the heat-removal portion of the fluid-circulator loop can be sandwiched in-between a first set of the transceiver modules having a first set optical transceivers and a second set of the transceiver modules having a second set optical transceivers.

In any embodiments of the apparatus, the fluid-circulator loop can form a closed loop locatable entirely within a perimeter of the circuit board.

In any embodiments of the apparatus, the heat-removal portion of the fluid-circulator loop can be located adjacent to only a sub-set of the optical transceiver modules, the sub-set can be part of an in-line set of the optical transceiver modules and the sub-set can be the most distally located ones of the plurality of the optical transceiver modules relative to incoming direction of air flow delivered to the circuit board.

In any embodiments of the apparatus, the circulating loop can be configured as a heat pipe and the fluid inside of the fluid-circulator loop can be configured to change phase during each circuit around to fluid-circulator loop.

In any embodiments of the apparatus, the fluid-circulator loop can be configured as pipe and the fluid inside of the fluid-circulator loop can be configured to remain in a liquid phase throughout each circuit around the fluid-circulator loop.

Any embodiments of the apparatus can further include a heat exchanger coupled to a heat-transfer portion of the fluid-circulator loop. In some such embodiments the heat exchanger can be located on the circuit board in a position that allows unobscured access to incoming forced air flow.

Any embodiments of the apparatus can further include a fluid pump connected to the fluid-circulator loop and configured to pump fluid through the fluid-circulator loop.

In any embodiments of the apparatus, the heat-removal portion of the fluid-circulator loop can contact a cold plate which in turn contacts the transceiver module or the optical transceiver.

Any embodiments of the apparatus can further include a liquid coolant manifold, wherein the heat-removal portion is located in between, and fluidly connected to, supply and return line portions of the fluid-circulator loop and the supply and return line portions fluidly connect the heat-removal portion to the liquid coolant manifold. In some such embodiments, the supply and return line portions connected to the liquid coolant manifold can be compliant connections.

Another embodiment is a method. The method comprises providing a fluid-circulator loop configured to be located on a circuit board, wherein a heat-removal portion of the fluid-circulator loop is configured to be located adjacent to at least one of a plurality of optical transceiver modules on the circuit board.

Any embodiments of the method can further include providing the circuit board and/or positioning the fluid-circulator loop on the circuit board, including locating the heat-removal portion of the fluid-circulator loop adjacent to a transceiver cage of the optical transceiver modules located on the circuit board configured to hold the at least one optical transceiver.

In any embodiments of the method, positioning the heat-removal portion of the fluid-circulator loop can include displacing the heat-removal portion connected to compliant supply and return line portions emanating from a single liquid coolant manifold, the displacing being in a direction normal to a mounting surface of the circuit board.

### BRIEF DESCRIPTION OF THE DRAWINGS

Various embodiments are best understood from the following detailed description, when read with the accompanying FIGUREs. Some features in the figures may be described as, for example, “top,” “bottom,” “vertical” or “lateral” for convenience in referring to those features. Such descriptions do not limit the orientation of such features with respect to the natural horizon or gravity. Various features may not be drawn to scale and may be arbitrarily increased or reduced in size for clarity of discussion. Reference is now made to the following descriptions taken in conjunction with the accompanying drawings, in which:

FIG. 1 presents a isometric view of an apparatus embodiment of the disclosure;

FIG. 2 presents a detailed exploded isometric view of another apparatus embodiment of the disclosure;

FIG. 3 presents a detailed plan view of an embodiment of the apparatus with cold plates and compliant fluid circulating loops;

FIG. 4A presents a detailed isometric view of another embodiment of the apparatus with cold plates and compliant fluid circulating loops;

FIG. 4B presents a detailed isometric view of another embodiment of the apparatus with cold plates and compliant fluid circulating loops; and

FIG. 5 presents a flow diagram illustrating an method embodiments of the disclosure such a method of manufacturing any of the embodiments of the apparatuses discussed in the context of FIGS. 1-4B.

### DETAILED DESCRIPTION

The description and drawings merely illustrate the principles of the invention. It will thus be appreciated that those skilled in the art will be able to devise various arrangements that, although not explicitly described or shown herein, embody the principles of the invention and are included within its scope. Furthermore, all examples recited herein are principally intended expressly to be only for pedagogical purposes to aid the reader in understanding the principles of the invention and the concepts contributed by the inventor(s) to furthering the art, and are to be construed as being without limitation to such specifically recited examples and conditions. Moreover, all statements herein reciting principles, aspects, and embodiments of the invention, as well as specific examples thereof, are intended to encompass equivalents thereof. Additionally, the term, “or,” as used herein, refers to a non-exclusive or, unless otherwise indicated. Also, the various embodiments described herein are not necessarily mutually exclusive, as some embodiments can be combined with one or more other embodiments to form new embodiments.

Thermal management strategies may use a heat sink coupled to a cage that houses one or more optical transceivers mounted to a circuit board. Air is blown over the outer surface of the heat sink and cage to help dissipate the heat generated from the transceivers. This strategy, however, may not provide sufficient heat removal as larger numbers of transceivers are place on a single board. For instance, for some of the optical transceiver modules arranged side-by-side in-line on a board, e.g., those transceivers most distal to the incoming air flow, may not have adequate heat removal due to preheating of the air passing over the transceivers that are more proximate to incoming air flow.

The inventors have recognized that heat removal from the transceivers can be enhanced by placing a fluid-circulator loop adjacent to least some of the transceivers. The high latent heat capacity of the fluid in the loop can facilitate large amounts of heat to be absorbed and transferred to another part of the board where heat can be removed from the board. The fluid-circulator loop facilitates the transfer of the heat generated by the transceivers to another location on the circuit board where the heat can be more efficiently removed as compared to blowing air directly over heat sinks coupled to the transceivers. As further illustrated below the fluid-circulator loop can be readily adapted for use with hot-swappable optical transceiver modules and/or form-fit transceiver modules with varying geometric tolerances.

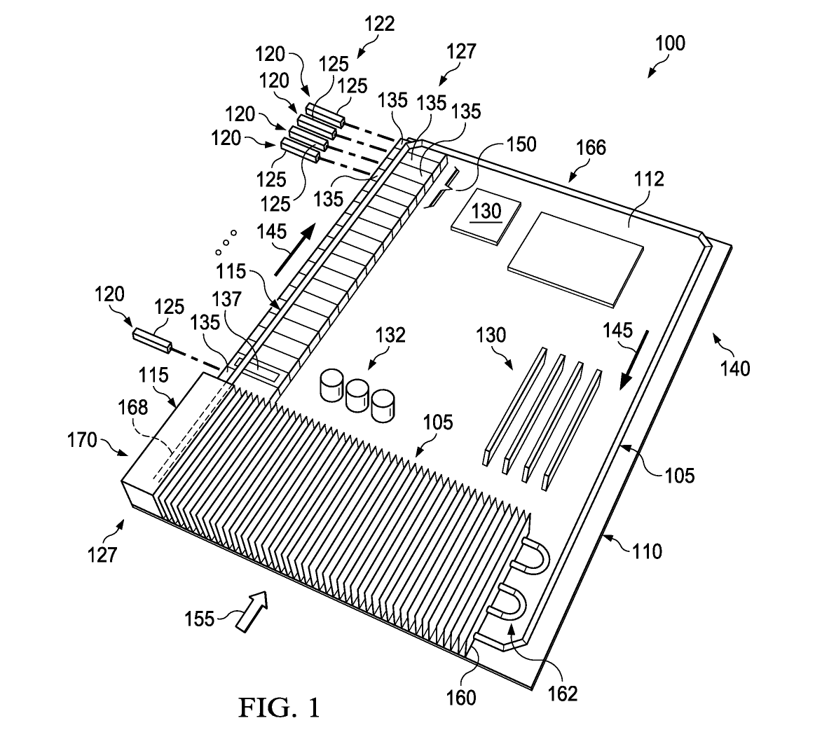

One embodiment of the disclosure is an apparatus. FIG. 1 presents an isometric view of an apparatus 100 of the disclosure. The apparatus 100 comprises a fluid-circulator loop 105 configured to be located on a circuit board 110 (e.g., on a surface 112 of the board 110). A heat-removal portion 115 of the circulating loop 105 is configured to be located adjacent to an optical transceiver module 120 on the circuit board 110.

As further illustrated in FIG. 1, in some embodiments, the apparatus 100 includes the circuit board 110 and a plurality of the optical transceiver modules 120. The modules 120 can situate at least one set 122 of optical transceivers 125 on the circuit board 110. For clarity, some optical transceiver 125 are shown unplugged from the module 120. For instance, the in-line set 122 of transceivers 125 can be situated along an edge 127 of the board 110 to facilitate plugging and unplugging the transceivers 125 into and out of the modules.

In some embodiments of the apparatus 100, the circuit board 110 can be one of many input/output boards for a communication apparatus 100. As also illustrated, the circuit board 110 can include various electronic components 130, 132, in addition to the optical transceiver modules 120. One skilled in the pertinent art would understand how the electronic components 130, 132, can be configured to process digital data encoded in optical signals transmitted through the transceivers 125 on the circuit board 110.

In some embodiments of the apparatus 100, the optical transceivers 125 are located inside of one or more transceiver cages 135 of one or more of the optical transceiver modules 120 and the heat-removal portion 115 of the circulating loop 105 contacts at least one of the transceiver cages 135 or the optical transceiver 125. e.g., via an opening 137 in the cage 135.

In some embodiments, the transceivers 125 in the set 122 can be a set of in-line, side-by-side transceivers 120. For instance, transceivers 125 can be separately housed inside of multiple transceiver cages 135 of multiple modules 120, or, the transceivers 125 can be housed inside of a single multi-opening cage of a single module 120. In other embodiments a single module 120 can include a plurality of transceiver cages 135 equal in number to the number of optical transceivers 125, and each transceiver cage 135 can accommodate individual optical transceivers 125. One skilled in the pertinent art appreciate other variants of optical transceiver 120 and transceiver cage 135 of the optical module 120.

In some embodiments of the apparatus 100, one or more optical transceivers 125 are located inside of one or more transceiver cages 135 of a plurality of the optical transceiver modules 120, and the optical transceivers 125 are small form factor hot-swappable pluggable transceivers. The term, hot-swappable pluggable transceivers, as used herein refers to a transceiver module 120 and transceiver 125 that allows the transceivers 125 to be insertable into or removable from the cage 135 without cessation of power to the circuit board 110 power and/or without a loss in the board's functionality. Non-limiting industry standard examples of the hot-swappable pluggable transceivers 125 include 10 gigabit small form factor pluggable transceivers (XFP) or, more generally, small form factor pluggable transceivers (SFP).

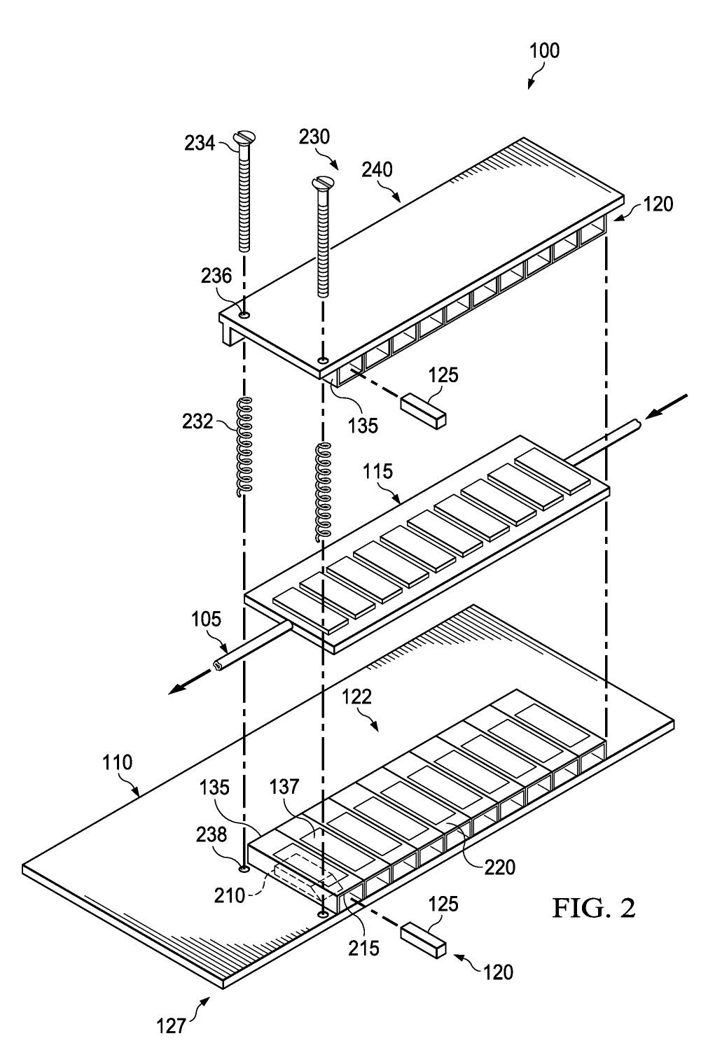

FIG. 2 presents a detailed exploded isometric view of another apparatus 100 embodiment of the disclosure. As illustrated in FIG. 2 an optical transceiver 125 is located inside of a transceiver cage 135 of the optical transceiver module 120 and the transceiver cage 135 further include a spring-loaded structure 210 configured to push the optical transceiver towards an interior surface 215 (e.g., an upper interior surface) of the transceiver cage 135. The interior surface 215 is proximate to the heat-removal portion 115 of the fluid circulating loop 105 that contacts the transceiver cage 135 or the optical transceiver 125. The spring-loaded structure 210 can facilitate direct physical contact between each of the optical transceivers 125 and their respective transceiver cages 135 and thereby reduce the thermal resistance between these components and enhance heat-removal from the transceiver modules 120 to the heat-removal portion 115 of the loop 105.

As further illustrated in FIG. 2, the heat-removal portion 115 of the circulating loop 115 contacts a surface 220 of the transceiver cage 135 or the optical transceiver 125 of one the modules 120. The contact surface 220 can correspond to all or a portion of the side of the cage 135 adjacent to the heat-removal portion 115. To facilitate heat transfer, the transceiver cage 135 and the heat-removal portion 115 can be held together and to the board 110 by a tensioning device 230.

Some embodiments of the tensioning device 230 can include a spring 232 and screw 234, but other coupling arrangement would be familiar to those skilled in the pertinent art. The screw 234 can attach to the board 110 and the spring 232 can regulate the amount of pressure applied to the heat-removal portion 115 and the transceiver cage 135. For instance, the spring 232 can control the pressure applied between the optical transceiver 125, cage 135 and heat-removal portion 115 of the loop 105 without compromising the plugability optical transceiver 125. The screw 234 can pass through openings 236 in one or more optical transceiver modules 120, 240 and openings 238 in the board 110 to facilitate coupling.

FIG. 2 further illustrates that some embodiments of the apparatus 100 can include a first set 122 of the transceiver modules 120 having a first set optical transceivers 125 (e.g., held in cages 135) and a second set 240 of the transceiver modules 120 having a second set optical transceivers 120. In some embodiments there can be multiple transceivers 125 e.g., from 1 to 50 transceivers 125 in the first or second sets 122, 240 all located on the board 110.

In some embodiments, to accommodate a large number of transceivers 125, different in-line sets 122, 240 of transceivers 125 can be stacked on top of each other. And, to facilitate heat removal from each of the transceivers 125 from both of the different sets 122, 240, the heat-removal portion 115 of the circulating loop 105 can be sandwiched in-between the first set 122 and second set 240 of the stacked transceiver modules 120.

In some embodiments, the heat-removal portion 115 of the loop 105 includes vapor chambers 245 (e.g., evaporator chambers) embedded within an interposer board 250. In some embodiments, the vapor chambers 245 and interposer board 250 are configured to locate each vapor chamber 245 located directly over a surface 220 of one of the optical transceiver cages 135 of the modules 120. As also illustrated in FIG. 2 the sets 122, 240 of transceiver modules 120, and the interposer board 250, holding the heat-removal portion 115, can all be held together and held to the board 110 by the tensioning device 230.

Returning to FIG. 1, as illustrated, in some embodiments of the apparatus 100, the fluid circulating loop 105 forms a closed loop locatable entirely within a perimeter 140 of the circuit board 110. Having the loop 105 entirely within the board's 110 perimeter 140 facilitates the board being hot swappable. That is, the board 110 can be replaced with another board without cessation of power to other boards 110 of the apparatus 100 and/or without affecting the functionality of other boards 110 of the apparatus 100.

As also illustrated in FIG. 1, in some embodiments of the apparatus 100, the heat removal portion 115 of the fluid circulating loop 105 can be located adjacent to each one of the plurality of optical modules 120 on the circuit board 110. The use of fluid with high specific heats, such as water, can accept heat input from the transceivers 125 held in the modules 120 to facilitate high rates of cooling uniformly across the entire set of optical transceiver modules 120. For instance, in some embodiments, the last module 120, and transceiver 125, in the fluid flow direction 145 through the loop 105 can be maintained at substantially within the same temperature (e.g., within ±10 percent in some embodiments) as the first module 120 and transceivers 125 in the fluid flow direction 145. For instance, in some embodiments, all of the optical transceivers 125 in a set 122 of modules 120 are maintained under an upper acceptable operating temperature of the optical transceivers 125 (e.g., less than about 70° C. for some embodiments).

In other embodiments of the apparatus 100, it can be advantageous for the heat-transfer portion of the circulating loop to be located only adjacent to those transceiver modules 120 found to be overheating, e.g., due to the inadequate cooling being provided from air flow over the board 110. Locating the heat-transfer portion 115 adjacent to only the over-heating transceiver modules 120 may also increase the ability of the loop 105 to dissipate heat, e.g., by avoiding any heat transfer from non-over-heating module 120 to the fluid circulating in the loop 105 and thereby avoiding preheating the fluid before reaching the over-heating transceiver modules 120.

In some embodiments, for instance, the heat-transfer portion 115 of the circulating loop 105 can be only located adjacent to a sub-set 150 of the optical transceiver modules 120 of transceivers 125. For instance, in some embodiments, the sub-set 150 can be the most distally located ones of the plurality of the optical transceiver modules 120 in the set relative to an incoming direction 155 of air flow to the circuit board 110.

In some embodiments, the circulating loop 105 is configured as a heat pipe and the fluid inside of the loop 105 changes phase during each circuit around to loop 105. One skilled in the pertinent art would understand how a small amount of fluid can sealed in a pipe, how the pipe can be evacuated to remove other gases and to reduce the pressure, and, how wicking structures can be introduced into the pipe to aid liquid movement due to capillary action. In such embodiments, the fluid in the loop 105 can be a dual-phase coolant. In such embodiments, the heat-removal portion 115 of the loop 105 can an evaporator portion and different portions of the loop 105 can be condenser portions.

In other embodiments, the fluid circulating loop 105 can configured as a pipe and the fluid inside of the loop 105 can remains in a liquid phase throughout each circuit around the loop 105.

As illustrated in FIG. 1, in some embodiments to enhance heat removal, the apparatus 100 further includes a heat exchanger 160 coupled to a heat-transfer portion 162 of the loop 105. For instance, the heat-transfer portion 162 of the loop 105 can be embedded within cooling fins 164 of the heat exchanger 160. In some embodiments, in facilitate heat removal, the fins 164 can be a row of metallic rectangular-shaped structures whose major surfaces are oriented perpendicular to the forced air flow direction 155 and to the board 110 major surface 112. In some embodiments, the heat-transfer portion 164 can be a condenser portion of the loop 105. As illustrated in FIG. 1, the flow of fluid exiting the heat-removal portion 115 can be fluidly connected to the heat-transfer portion 162 via a return line portion 166 of the loop 105 and the flow of fluid exiting the heat-transfer portion 162 can be fluidly connected to the heat-removal portion 115 via a supply line portion 168 of the loop 105, e.g., to form a closed loop.

As illustrated in FIG. 1, in some embodiments, the heat exchanger 160 is located on the circuit board 100 in a position that allows unobscured access to an incoming forced air flow 155, e.g., from a fan of the apparatus. That is, at least a portion of the incoming air flow to the board 110 can reach the heat exchanger 160 without being obstructed by any other components 130, 132 on the circuit board including transceiver modules 120.

As illustrated in FIG. 1, in some embodiments, to facilitate heat removal, the apparatus 100 further includes a fluid pump 170 connected to the loop 105 and configured to pump fluid through the loop 105. For instance, in some embodiments fluid pump 170 can be a piezoelectric micro-pump and configured to circulate a liquid phase of the fluid through the loop 105, however, other pumping mechanisms could be employed. In some embodiment, the pump 170 can be located between the heat-transfer portion 162 and heat-removal portion 115, and in some embodiments, the pump 170 can be fluidly coupled to the supply line portion 168 of the loop 105.

In some embodiments, both the heat exchanger 160 and the fluid pump 170 can be located on the circuit board 110, e.g., entirely within a perimeter 140 of the circuit board 110, to facilitate the board 110 having hot-swappable capabilities.

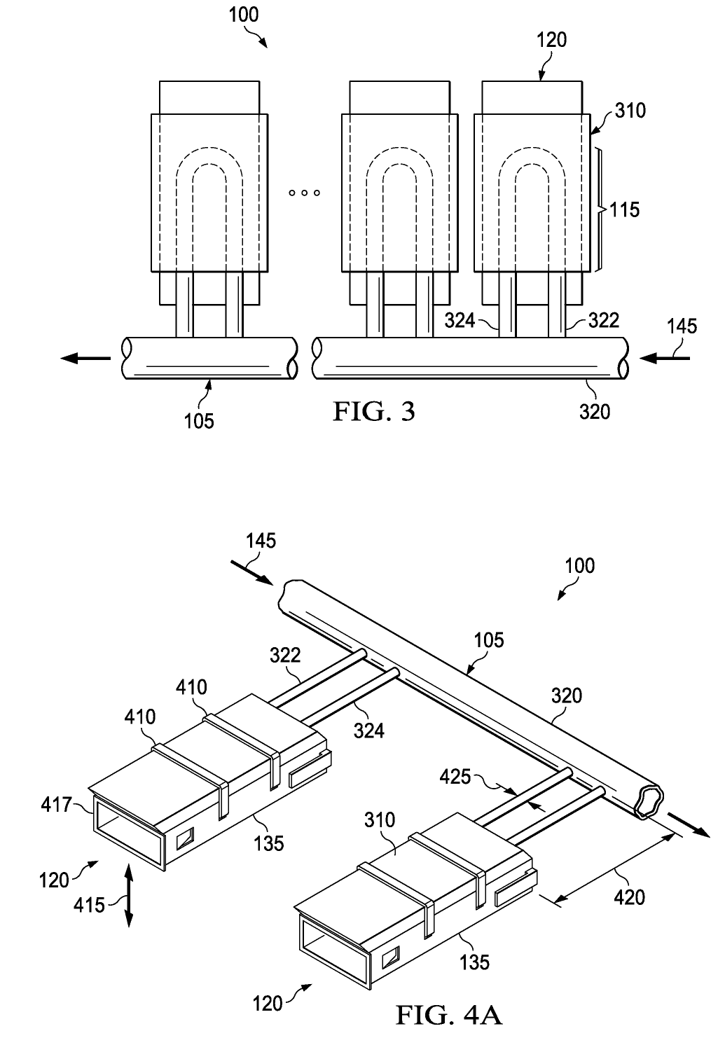

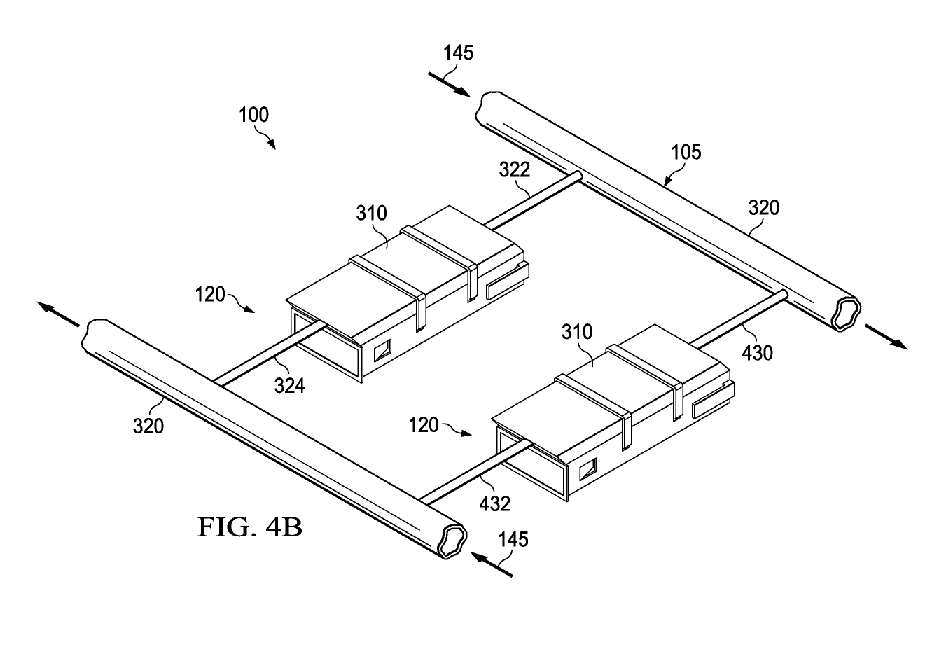

FIG. 3 presents a detailed plan view of another embodiment of the apparatus and FIG. 4 presents a detailed isometric view of another embodiment of the apparatus.

As illustrated in FIG. 3, in some embodiments of the apparatus 100, the heat-removal portion 115 of the circulating loop contacts a cold plate 310, which in turn, contacts a transceiver module 120. For instance, the cold plate can be made of aluminum, copper or other highly thermally conductive material to facilitate heat-transfer. For instance, the cold plate 310 can contact a transceiver cage 135 or the optical transceiver 125 of a module 120 housing at least one optical transceiver 125 (FIG. 1). For instance, heat-removal portion 115 of the loop 105 can be on or embedded in the cold plate 310. In some embodiments such as when using high powered (e.g., greater than about 1 W) transceiver modules 120, it is advantageous for the cold plate 310 to directly contact the optical transceiver 125 through an opening 137 in the cage 135. In some embodiments such as when using lower powered (e.g., less than or equal to about 1 W) transceiver modules 120, the cold plate 310 can to directly contact the cage 135. In either such embodiments a spring-loaded structure 210 mounted in the cage 135 can facilitate contacting the inner surface 215 of the top side of the cage 135.

As illustrated in FIG. 4, in some embodiments the cold plate 310 and heat-removal portion 115 can be coupled together via a spring-clip mechanism 410. The spring-clip mechanism 410 can help to orient the cold plate 310 or heat-removal portions 115 at a desired location on the cage and provide a compressive force to facilitate direct contact and hence effective heat transfer.

As further illustrated, some embodiments of the apparatus 100, further includes a liquid coolant manifold 320, wherein the heat-removal portion 115 is located in-between, and fluidly connected to, supply and return line portions 322, 324 of the loop 105. The supply and return line portions 322, 324 fluidly connect the heat-removal portion 115 to the liquid coolant manifold 320. In some embodiments, the liquid coolant manifold 310 can be part of the fluid circulating loop 105, and the liquid coolant manifold 310 can be entirely located on the circuit board 110 and be part of a closed fluid circulating loop. However, in some embodiments the liquid coolant manifold 310 can be connected to a heat exchanger that is extraneous to the board 110.

As illustrated there can be a plurality of separate heat-removal portions 115 and supply and return line portions that 322, 324 are each separately connected in parallel to single central liquid coolant manifold 310. However in series connection with one or more the liquid coolant manifolds 310 are contemplated as are combinations of in series and in parallel connections between heat-removal portions 115 and the manifold 310 or manifolds 310.

In some embodiments, the supply and return line portions 322, 324 of the loop 105 are compliant connections. The term compliant connection as used herein refers to the line portions 322, 324 having the ability to flex or reversibly displace in a direction 415 (FIG. 4A) to accommodate size variations in the optical transceiver module 120 and/or cold plate 310. The compliant connection is elastically deformable in that the displacement is reversible with substantially no permanent set or deformation. For instance, as illustrated in FIG. 4A, in some embodiments the compliant supply and return line portions 322, 324 are cantilevered connections that protrude or emanate from the liquid coolant manifold 320 portion of the loop 105. In some embodiments, the cantilevered supply and return line portions 322, 324 allow the heat-removal portion 115 or cold plate 310 (e.g., a distal tip 417 of the heat-removal portion 115 or plate 310) to be displaceable in a direction 415 (FIG. 4) that is perpendicular a mounting surface 112 of the circuit board 110. As non-limiting examples, in some cases, the displacement can be a maximum distance of least about 0.1 mm, and in some embodiments, a maximum distance in a range of about 0.1 mm to about 0.2 mm.

Having compliant (e.g., cantilevered) supply and return line portions facilitates accommodation of manufacturing variations in geometric tolerances of the optical transceiver module 120, e.g., the transceiver cage 135. Manufacturing variations optical transceiver module 120 can cause gaps to exist between a rigid cold plate 310, or a rigid heat-removal portion 115, thereby greatly reduce the ability of heat to be removed from the module 120 by the loop 105. For instance, there can be substantial variations in the efficiency of heat removal from the individual transceiver modules for a set 122 of in-line modules 120 when the adjacent heat removal portion 115 or cold plate 310 has a rigid structure. Having cantilevered supply and return line portions 322, 324 can provide individual, independent, mechanically “floating” or compliant heat-removal portions 115 or cold plates 310 to facilitate direct contact with the transceiver cages 135 or the optical transceiver 125.

In some embodiments, compliant connections between the supply and return line portions 322, 324 of the loop 105 can be achieved without the use of cantilevered connections. For example, if two or more sets of separate supply (e.g., lines 324 and 430) and return coolant lines (e.g., lines 324 and 432) are used, the cold plate 310 can be compliantly supported like a trampoline (or hammock) between the first set of lines 322, 430 and the second set of lines 324, 432 such as illustrated in FIG. 4B.

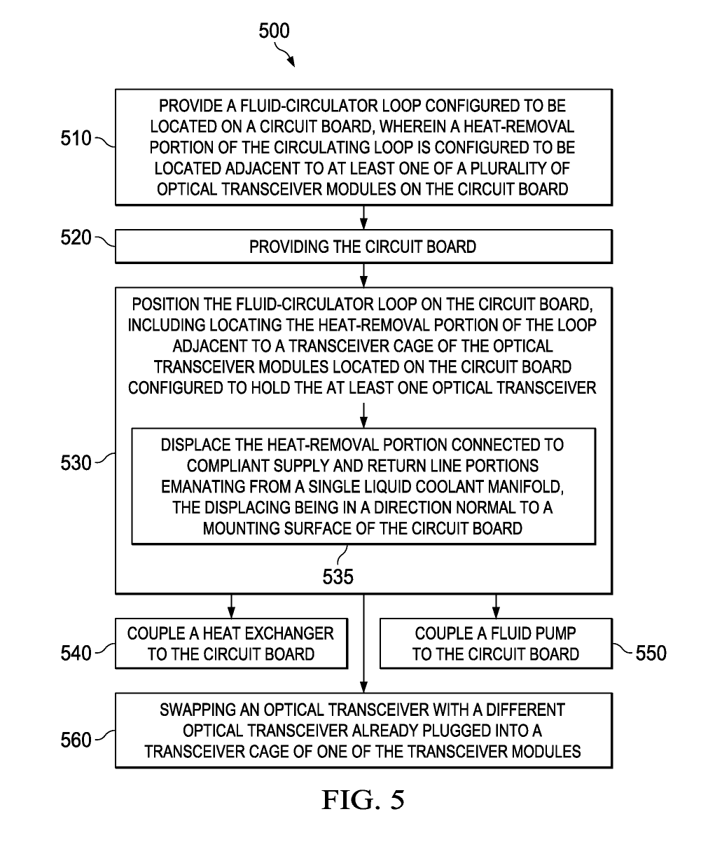

Another embodiment is a method, e.g., a method of assembling an apparatus. FIG. 5 presents a flow diagram illustrating a method 500 for assembling an apparatus of the disclosure such as the any of the embodiments of the apparatuses 100 discussed in the context of FIGS. 1-4B.

With continuing references to FIGS. 1-4B throughout, as illustrated in FIG. 5, the method 500 comprises a step 510 of providing a fluid-circulator loop 105 configured to be located on a circuit board 110. A heat-removal portion 115 of the circulating loop 105 is configured to be located adjacent to at least one of a plurality of optical transceiver modules 120 on the circuit board 105.

One skilled in the pertinent art would understand how to provide the fluid-circulator loop 105 in accordance with step 510, so as to have sufficient heat removal capacity and in some embodiments, have to have the optional cantilevered connection portions 322, 324.

For instance, one skilled in the pertinent art would understand how solid mechanics and elastic bending theory could be applied to design of the mechanical compliance or flexibility for cantilevered support of the cold plate 310 and/or heat removal portion 115. For instance, the geometery of supply and return line portions 322, 324 can be designed to accommodate the desired vertical deflection 415 needed to assure sufficient cold plate 310 contact to the transceiver module 120, under the action of the compressive force induced by the spring-clip mechanism 415 during module insertion. For instance, for a given target fluid flow rate through the loop 105 and material composition (e.g., aluminum, copper or other highly thermally conductive material), parameters such as the distance 420 out from the manifold 330, the diameter 425 and thickness supply and return line portions 322, 324 can be calculated based on these theories to provided the desired flexible displacement.

Some embodiments of the method 500 further include a step 520 of providing the circuit board 110 and a step 530 of positioning the fluid-circulator loop 105 on the circuit board 110. Positioning the loop 105, in step 530 includes locating the heat-removal portion 115 of the loop 105 adjacent to transceiver cages 135 of the optical transceiver modules 120 located on the circuit board 110. In some embodiments, as part of step 530, the modules 120, heat-removal portion 115, and in some cases, optional cold plate 310 can be held together and to the board 110 using a tensioning device 230 (FIG. 2) or spring-clip mechanism 410 (FIGS. 3 and 4) or combinations thereof.

In some embodiments of the method 500, positioning the fluid-circulator loop 105 (step 530) include a step 535 of displacing the heat-removal portion 115, which is connected to compliant supply and return line portions 322, 324 emanating from a single liquid coolant manifold 320. The displacing in step 535 is in a direction 415 perpendicular to a mounting surface 112 of the circuit board 110, e.g., so as to accommodate the transceiver cage 135 between the heat-removal portion 115 and the mounting surface 112.

Embodiments of the method 500 can include a step 540 of coupling the heat exchanger 160 to the circuit board 110 or a step 550 of coupling the fluid pump 170 to the circuit board 110, such as described in the context of FIG. 1. Embodiments of the method 500 can include a step 560 of swapping an optical transceiver 125 with a different optical transceiver already plugged into a transceiver cage 135 of one of the transceiver modules 120. In some embodiments, for instance, swapping in step 560 can be hot-swapping and accomplished without cessation of electrical power to the circuit board 110.

Additional steps to complete assembly, or alter the assembled apparatus 100, in accordance with the method 500 would be apparent to one skilled in the pertinent arts based on the embodiments discussed above.

Although various embodiments of the present invention has been described in detail, those skilled in the art should understand that they can make various changes, substitutions and alterations herein without departing from the scope of the claimed inventions.

What is claimed is:

1. An apparatus, comprising:
a fluid-circulator loop configured to be located on a circuit board, wherein a heat-removal portion of the fluid-circulator loop is configured to be located adjacent to an optical transceiver module on the circuit board.

2. The apparatus of claim 1, further including:
the circuit board; and
a plurality of the optical transceiver modules arranged to situate at least one set of in-line optical transceivers on the circuit board.

3. The apparatus of claim 1, wherein optical transceivers are located inside of one or more transceiver cages of one of more of the optical transceiver modules and the heat-removal portion of the fluid-circulator loop contacts at least one of the transceiver cages or the optical transceivers.

4. The apparatus of claim 1, wherein one or more optical transceivers are located inside of one or more transceiver cages of a plurality of the optical transceiver modules, and the optical transceivers are small form factor hot-swappable pluggable transceivers.

5. The apparatus of claim 1, wherein an optical transceiver is located inside of a transceiver cage of the optical transceiver module, and the transceiver cage further include a spring-loaded structure configured to push the optical transceiver towards an interior surface of the transceiver cage, the interior surface being proximate to the heat-removal portion of the fluid-circulator loop that contacts the transceiver cage or the optical transceiver.

6. The apparatus of claim 1, wherein the heat-removal portion of the fluid-circulator loop contacts a surface of transceiver cage or the optical transceiver of the optical transceiver modules, and, the transceiver cage and the heat-removal portion are held together and to the board by a tensioning device.

7. The apparatus of claim 1, wherein the heat-removal portion of the fluid-circulator loop is sandwiched in-between a first set of the transceiver modules having a first set optical transceivers and a second set of the transceiver modules having a second set optical transceivers.

8. The apparatus of claim 1, wherein the fluid-circulator loop forms a closed loop locatable entirely within a perimeter of the circuit board.

9. The apparatus of claim 1, wherein the heat-removal portion of the fluid-circulator loop is located adjacent to only a sub-set of the optical transceiver modules, the sub-set being part of an in-line set of the optical transceiver modules and the sub-set being the most distally located ones of the plurality of the optical transceiver modules relative to incoming direction of air flow delivered to the circuit board.

10. The apparatus of claim 1, wherein the fluid-circulator loop is configured as a heat pipe and the fluid inside of the fluid-circulator loop is configured to change phase during each circuit around the fluid-circulator loop.

11. The apparatus of claim 1, wherein the fluid-circulator loop is configured as pipe and the fluid inside of the fluid-circulator loop is configured to remain in a liquid phase throughout each circuit around the fluid-circulator loop.

12. The apparatus of claim 1, further including a heat exchanger coupled to a heat-transfer portion of the fluid-circulator loop.

13. The apparatus of claim 12, wherein the heat exchanger is located on the circuit board in a position that allows unobscured access to incoming forced air flow.

14. The apparatus of claim 1, further including a fluid pump connected to the fluid-circulator loop and configured to pump fluid through the fluid-circulator loop.

15. The apparatus of claim 1, wherein the heat-removal portion of the fluid-circulator loop contacts a cold plate which in turn contacts the transceiver module.

16. The apparatus of claim 1, further including a liquid coolant manifold, wherein the heat-removal portion is located in between, and fluidly connected to, supply and return line portions of the fluid-circulator loop and the supply and return line portions fluidly connect the heat-removal portion to the liquid coolant manifold.

17. The apparatus of claim 16, wherein the supply and return line portions connected to the liquid coolant manifold are compliant connections.

18. A method, comprising:
providing a fluid-circulator loop configured to be located on a circuit board, wherein a heat-removal portion of the fluid-circulator loop is configured to be located adjacent to at least one of a plurality of optical transceiver modules on the circuit board.

19. The method of claim 18, further including:
providing the circuit board; and
positioning the fluid-circulator loop on the circuit board, including locating the heat-removal portion of the fluid-circulator loop adjacent to a transceiver cage of the optical transceiver modules located on the circuit board configured to hold the at least one optical transceiver.

20. The method of claim 18, positioning the heat-removal portion of the fluid-circulator loop includes displacing the heat-removal portion connected to compliant supply and return line portions emanating from a single liquid coolant manifold, the displacing being in a direction normal to a mounting surface of the circuit board.
